(19) United States
(12) Patent Application Publication
(10) Pub. No.: US 2005/0102831 A1
(43) Pub. Date: May 19, 2005

(54) Process for manufacturing a wiring substrate

(76) Inventors: Hajime Saiki, Nagoya-shi (JP); Atsuhiko Sugimoto, Nagoya-shi (JP)

Correspondence Address: STITES & HARBISON PLLC, 1199 NORTH FAIRFAX STREET, SUITE 900, ALEXANDRIA, VA, 22314, US

(21) Appl. No.: 10/989,516

(22) Filed: Nov. 17, 2004

(30) Foreign Application Priority Data
Nov. 18, 2003 (JP) P.2003-388491

(51) Int. Cl. H05K 3/02; C25F 3/00

(52) U.S. Cl. 29/852; 29/846; 216/108

(57) ABSTRACT

A process for manufacturing a wiring substrate, comprising a roughening step of roughening surfaces of insulating resin layers, at least one of the insulating resin layers containing an epoxy resin which contains 30 to 50 wt. % of an inorganic filler of SiO₂ having an average grain diameter of 1.0 to 10.0 μm, wherein the roughening step includes a roughening step of dipping in a solution of permanganic acid at 70 to 85° C. for 20 minutes or longer.

### FIELD OF THE INVENTION

The present invention relates to a wiring substrate manufacturing method capable achieving a reliable adhesion between wiring pattern layers (e.g., built-up wiring layers) formed at a fine pitch and insulating resin layers adjoining the former.

### BACKGROUND OF THE INVENTION

According to the trend of recent years for a high performance and a high signal-processing rate, there has been enhanced a demand for making the size of the wiring substrate smaller and the pitch of the wiring pattern layers (e.g., built-up wiring layers) finer.

For example, an insulating resin layer between one wiring pattern layers and two adjoining wiring pattern layers is generally restricted by a practical limit of the section of a length×a width of 25 μm×25 μm. However, it has been demanded that the length and the width are individually 20 μm or less.

In order to satisfy these demands, it As necessary not only to form the wiring pattern layer precisely in shape and size but also to enhance the adhesion better between the wiring pattern layers and the adjoining insulating resin layers. In order to enhance that adhesion, the surfaces of the insulating resin layers are subjected to a roughening treatment and are then plated with copper to form wiring pattern layers. The aforementioned roughening treatment is performed at a step of treating the surfaces of the insulating resin layers with a permanganic acid after subjected to a swelling treatment (as referred to Japanese Patent No. 3,054,388 (pages 3 to 4, Column No. (0017)), for example)

When the wiring pattern layers of the fine pitch are to be formed or when the via conductors to connecting the overlying wiring pattern layers and the underlying wiring pattern layers are to be radially reduced, however, the current roughening treatment of the insulating resin layers and their surfaces may have an insufficient adhesion between the fine-pitched wiring pattern layers and the adjoining insulating resin layers.

Incidentally, the existing insulating resin layers are made of an epoxy resin containing about 18 wt. % (% by weight) of SiO₂ filler, and have properties of an elongation: 7.6%, a Young's modulus: 3.5 GPa, and a thermal expansion coefficient in a planar (X-Y) direction: about 60 ppm/° C. On the other hand, the existing roughening treatment performs a swelling treatment at about 80° C. for 5 minutes, and a dipping treatment in NpMnO₄.3H₂O or KMnO₄ at about 80° C. for 10 minutes.

### SUMMARY OF THE INVENTION

The invention contemplates to solve the aforementioned problems in the background art, and has an object to provide a wiring substrate manufacturing process which can achieve a reliable adhesion between wiring pattern layers or via conductors formed at a fine pitch and insulating resin layers adjoining the former.

In order to achieve the aforementioned object, the invention has -been conceived by noting that the composition and properties of insulating resin layers and the roughening treatment of their surfaces are optimized.

Specifically, according to the invention, there is provided a process for manufacturing a wiring substrate, comprising a roughening step of roughening the surfaces of insulating resin layers, at least one of the insulating resin layers (preferably, each of the insulating resin layers) including an epoxy resin containing 30 wt. % or more and 50 wt. % or less of an inorganic filler of SiO₂ having an average grain diameter of 1.0 μm or more and 10.0 μm or less, wherein the roughening step includes a roughening step of dipping in a solution of permanganic acid at 70° C. or higher and at 85° C. or lower for 20 minutes or longer. Preferably, at least one of the insulating resin layers (more preferably, each of the insulating resin layers) includes 50 to 70 wt. % of the epoxy resin.

According to this process, the permanganic acid solution is caused to contact for a long time with the surfaces of the insulating resin layers containing more inorganic filler so that a number of continuous asperities are formed on the surfaces of the insulating resin layers. Therefore, the wiring pattern layers formed at the fine pitch can be firmly adhered to those asperated surfaces There can also be provided a wiring substrate manufacturing process, wherein the surfaces of the insulating resin layers include the inner wall faces of via holes extending through those insulating resin layers. According to this process, the asperities are also formed in the inner wall faces of the via holes extending through the insulating resin layers so that via conductors to be formed in the via holes can also be firmly adhered.

Here, the permanganic acid solution includes sodium permanganate (NaMnO₄.3H₂O) or potassium permanganate (KMnO₄).

According to the invention, there is further provided, as a preferable embodiment, a wiring substrate manufacturing process, wherein at least one of the insulating resin layers (preferably, each of the insulating resin layers) after the roughening step have a surface roughness of Ra: 0.2 μm or more and 1.0 μm or less.

According to this process, the surface roughness of the insulating resin layers after the roughening step are within a proper range so that the wiring pattern layers to be formed on the surfaces of the insulating resin layers can be firmly adhered. It is preferred that the insulating resin layers have a surface roughness of Ra: 0.2 μm or more and 1.0 μm or less and Rz: 0.2 μm or more and 1.0 μm or less. Here, the roughness Ra indicates a center line average roughness, and the roughness Rz indicates a ten-point average roughness.

There can be further provided, as a preferable embodiment, a wiring substrate manufacturing process, wherein at least one of the insulating resin layers (preferably, each of the insulating resin layers) has an elongation of 6% or less (but excepting 0).

According to this process, the elongation is lower than that of the insulating resin layers of the prior art. It is, therefore, possible to stably keep the state, in which the wiring pattern layers are firmly adhered to the asperities formed by the roughening step on the surfaces of the insulating resin layers.

There can be further provided, as a preferable embodiment, a wiring substrate manufacturing process, wherein at least one of the insulating resin layers (preferably, each of the insulating resin layers) has a Young's modulus of 3.6 GPa or more and 5.0 Gpa or less.

According to this process, the Young's modulus is higher than those of the insulating resin layers of the prior art, so that influences from an external force can be suppressed from the state, in which the wiring pattern layers to be formed on the roughened surfaces of the insulating resin layers are firmly adhered.

There can be further provided, as a preferable embodiment, a wiring substrate manufacturing process, wherein at least one of the insulating resin layers (preferably, each of the insulating resin layers) has a thermal expansion coefficient in a planar (X-Y) direction: 50 ppm/° C. or less (but excepting 0). According to this process, the thermal expansion coefficient is lower than that of the insulating resin layers of the prior art so that the influences due to the thermal change can be suppressed from the state, in which the wiring pattern layers to be formed on the surfaces of the insulating resin layers are firmly adhered.

There can be further provided, as a preferable embodiment, a wiring substrate manufacturing process which further comprises, after the roughening step, the step of forming wiring pattern layers of a predetermined pattern on the roughened surfaces of the insulating resin layers after the roughening step.

According to this process, the wiring pattern layers are formed while being firmly adhered to the roughened surfaces of the insulating resin layers, so that they can keep the shaping and sizing precisions even they are formed to have a pattern of a fine pitch containing narrow wiring lines.

There can be further provided, as a preferable embodiment, a wiring substrate manufacturing process further comprising, after the roughening step, the step of forming via conductors on the roughened inner wall faces of via holes formed in advance through the insulating resin layers. According to this process, the via conductors formed in the via holes can be firmly adhered to the adjoining insulating resin layers.

### BRIEF DESCRIPTION OF THE DRAWINGS

FIG. 1 is a schematic section showing one step of a process for manufacturing a wiring substrate according to the invention;

FIG. 2 is a schematic section showing a manufacturing process subsequent to FIG. 1;

FIG. 3 is a schematic section showing a manufacturing process subsequent to FIG. 2;

FIG. 4 is a schematic section showing a manufacturing process subsequent to FIG. 3;

FIG. 5 is a schematic section showing a manufacturing process subsequent to FIG. 4;

FIG. 6 is an enlarged view of a portion X indicated by single-dotted lines in FIG. 5 and a schematic section showing a manufacturing process subsequent to FIG. 5;

FIG. 7 is a schematic section showing a manufacturing process subsequent to FIG. 6;

FIG. 8 is a schematic section showing a manufacturing process subsequent to FIG. 7;

FIG. 9 is a schematic section showing a manufacturing process subsequent to FIG. 8;

FIG. 10 is a schematic section showing a manufacturing process subsequent to FIG. 9; and

FIG. 11 is a schematic section showing the manufacturing steps subsequent to FIG. 10 and a wiring substrate obtained.

### DETAILED DESCRIPTION OF THE INVENTION

The best mode for carrying out the invention will be described in the following. But, the invention is not limited to the range.

FIG. 1 is a section showing a core substrate 1 made of a bismaleimide triazine (BT) resin having a thickness of about 0.7 mm. This core substrate 1 is covered on its surface 2 and a back 3, respectively, with copper foils 4 and 5 having a thickness of about 70 μm. The not-shown photosensitive/insulating dry film is formed over those copper foils 4 and 5 and is subjected to an exposure and a development of a predetermined pattern. After this, the etching resist obtained is removed with a peeling liquid (according to the well-known subtractive method).

Here, a multi-panel having a plurality of core substrates 1 of product units may be used so that the individual core substrates 1 may be subjected to a similar treatment step (as in the following individual steps).

As a result, the cooper foils 4 and 5 become wiring layers 4 and 5 profiling the aforementioned pattern, as shown in FIG. 2.

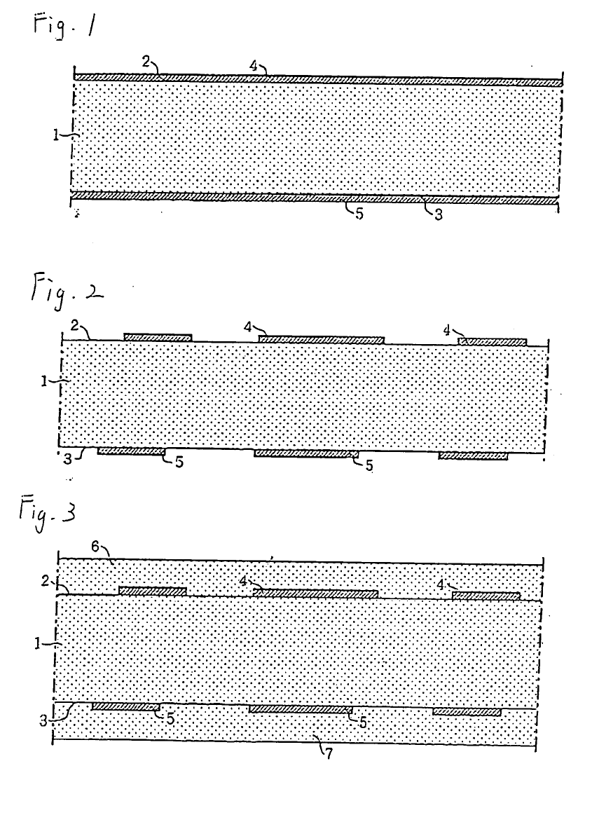

Next, the surface 2 of the core substrate 1 and the wiring layer 4, and the back 3 and the wiring layer 5 are individually covered thereover (or under the wiring layer 5) with an insulating film made of an epoxy resin containing an inorganic filler, as shown in FIG. 3, to form insulating resin layers 6 and 7.

These insulating resin layers 6 and 7 have a thickness of about 40 μm, and contain an epoxy resin containing 30 to 50 wt. % (e.g., 36 wt. % in this embodiment) of an inorganic filler made of substantially spherical SiO₂ (each of the insulating resin layers 6 and 7 contains 64 wt. % of the epoxy resin in this embodiment). At the same time, the insulating resin layers 6 and 7 have properties of an elongation: 6% or less (e.g., 5.0% in thisembodiment) , a Young's modulus: 3.6 to 5 GPa (e.g., 4.0 GPa in this embodiment), and a thermal expansion coefficient in a planar (X-Y) direction: about 50 ppm/° C. or less (e.g., 46 ppm/° C. in this embodiment).

Here, the inorganic filler has an average grain diameter of 1.0 μm or more and 10.0 μm or less. Here, the aforementioned substantially spherical shape includes an ellipsoide and so on.

Next, as shown in FIG. 4, the core substrate 1, the wiring layers 4 and 5 and the insulating resin layers 6 and 7 are bored at their predetermined position with a drill to form a through hole 8 having an internal diameter of about 200 μm.

Moreover, the surfaces of the insulating resin layers 6 and 7 are irradiated at their predetermined positions and along their thickness direction with the not-shown laser (e.g., a carbon monoxide gas laser in this embodiment). As a result, there are formed substantially conical via holes 10 and 11, which extend through the insulating resin layers 6 and 7 so that the wiring layers 4 and 5 are exposed to the bottom faces thereof, as shown in FIG. 5.

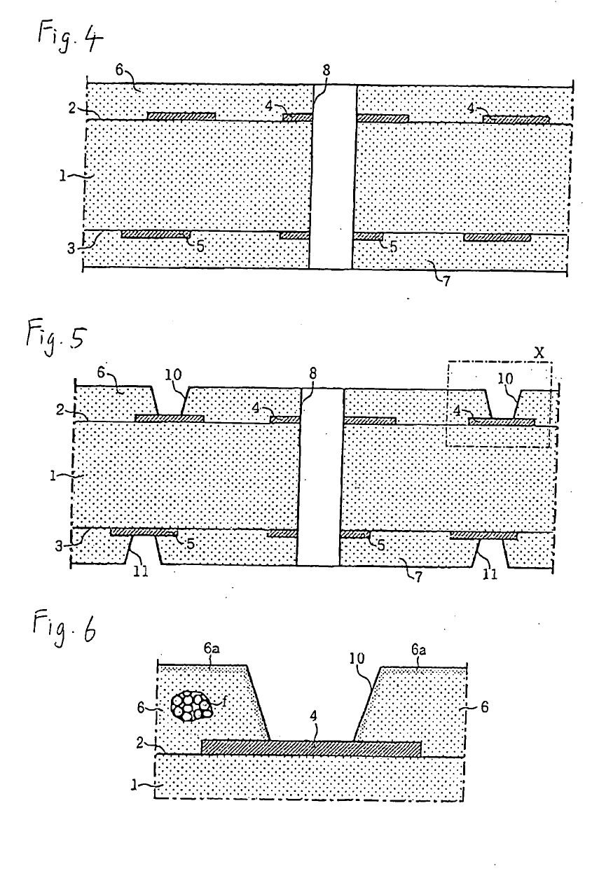

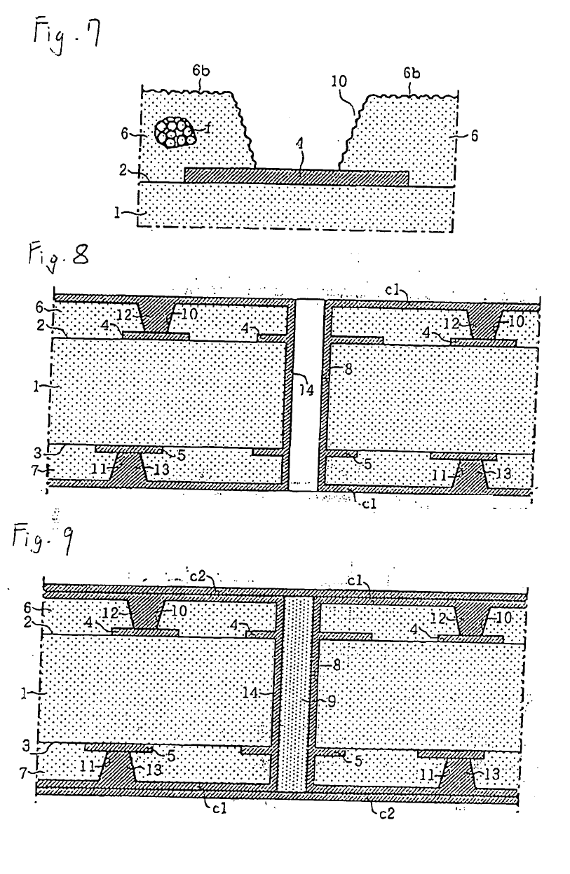

Next, a roughening step (or a desmearing treatment) of the invention will be described by way of example of FIGS. 6 and 7 presenting enlarged views of a single-dotted portion X in FIG. 5.

The insulating resin layers 6 and 7 having the via holes 10 and 11 formed therein are subjected on their surfaces to a swelling treatment at 60 to 80° C. for 5 to 10 minutes. Specifically, the core substrate 1 or a panel having a plurality of core substrates is rinsed in advance with water, and is dipped in a solution belonging to the aforementioned temperature band and containing diethyl glycol-n-butyl ether, an anionic surface active agent and sodium hydroxide.

As a result, a weak surface layer portion 6a (7a) having the aforementioned solution penetrated to take a swelling state is formed to have a thickness of about 30 μm on the surface of the insulating resin layer 6 (7) and the inner wall face of the via hole 10 (11).

Here, reference letter f in FIGS. 6 and 7 designates an inorganic filler of SiO₂.

Next, the core substrate 1 or the panel subjected to the aforementioned swelling treatment is rinsed with water. After this, the surface layer portion 6a (7a) of the insulating resin layer 6 (7) having the via holes 10 and 11 formed therein is subjected to a roughening treatment, in which it is dipped for 20 minutes or more (e.g., 30 minutes) in either NaMnO₄-3H₂O or KMnO₄ at 70 to 85° C. (e.g., 80° C.).

As a result, a roughened face 6b (7b), which are roughened from the surface layer portion 6a (7a) to have a number of asperities, is formed on the surface of the insulating resin layer 6 (7) and the inner wall face of the via hole 10 (11). This roughened face 6b (7b) has a roughness of Ra: 0.2 μm or more and 1.0 μm or less and Rz: 0.2 μm or more and 1.0 μm or less. In this meanwhile, the inner wall face of the through hole 8 is likewise roughened.

Moreover, a plating catalyst containing Pd is applied to the roughened inner wall face of the via hole 10 (11), the roughened face 6b (7b) of the insulating resin layer 6 (7) and the inner wall face of the through hole 8. After this, those faces are electrolessly and electrically plated with copper.

As a result, copper-plated films cl are formed all over the surfaces of the insulating resin layers 6 and 7, and a substantially cylindrical through-hole conductor 14 having a thickness of about 40 μm is formed in the through hole 8, as shown in FIG. 8. At the same time, the via holes 10 and 11 are additionally plated therein with copper to form filled via conductors 12 and 13.

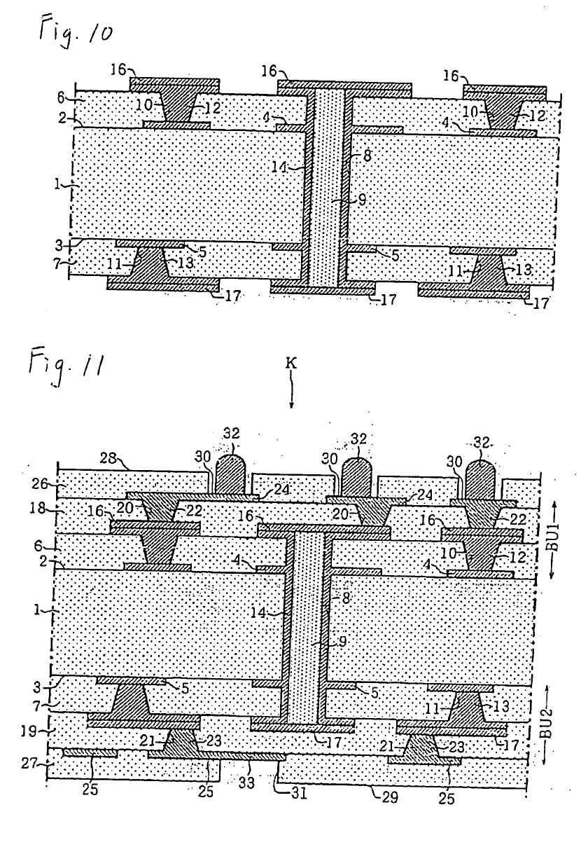

Next, the through-hole conductor 14 is filled on its inner side with a filler resin 9 containing an inorganic filler like before, as shown in FIG. 9. Here, the filler resin 9 may be either a conductive resin containing metal powder or an inconductive resin.

As shown in FIG. 9, moreover, the upper faces of the copper-plated films c1 and c1 and the two end faces of the filler resin 9 are electrically plated with copper to form copper-plated films c2 and c2. Simultaneously with this, the filler resin 9 is cover-plated on its two end faces. Here, the copper-plated films c1 and c2 have n entire thickness of about 15 μm.

Next, the not-shown photosensitive/insulating dry film is formed over the copper-plated films c1 and c2 and the copper-plated films Bb and 11b, and is subjected to an exposure and a development of a predetermined pattern. After this, the etching resist obtained and the copper-plated films c1 and c2 lying just below the former are removed with a well-known peeling liquid. As a result, wiring pattern layers 16 and 17 profiling the aforementioned pattern are formed on the surfaces of the insulating resin layers 6 and 7, as shown in FIG. 10.

The wiring pattern layers 16 and 17 and the via conductors 12 and 13 can acquire a strong adhesion to the insulating resin layers 6 and 7, no matter whether the wiring pattern layers 16 and 17 might be narrowed at a fine pitch or the via conductors 12 and 13 might be radially reduced, because the surfaces of the insulating resin layers 6 and 7 adjoining the layers 16 and 17 and the conductors 12 and 13 are roughened (at 6b and 7b).

As shown in FIG. 11, moreover, the insulating resin layer 6 and the wiring pattern layer 16, and the insulating resin layer 7 and the wiring pattern layer 17 are individually covered thereover (or under the layers 7 and 17) with an insulating film having a thickness like before to form insulating resin layers 18 and 19.

Next, the insulating resin layers 18 and 19 are irradiated on their surfaces at predetermined positions and along their thickness direction with the not-shown laser, to form substantially conical via holes 20 and 21, which extend through the insulating resin layers 18 and 19 so that the wiring pattern layers 16 and 17 are exposed to the bottom faces thereof, as shown in FIG. The entire surfaces of the insulating resin layers 18 and 19 including the inner wall faces of the via holes 20 and 21 are subjected to a roughening step including the swelling treatment and the roughening treatment like before, thereby to form roughened faces having a number of asperities like before.

Next, a plating catalyst like before is applied in advance to the entire surfaces of the roughened insulating resin layers 18 and 19 including the aforementioned via holes 20 and 21.* After-this, the entire surfaces are electrolessly plated with copper to form a (not-shown) thin copper film layer having a thickness of about 0.5 μm.

Next, the entire surface of the thin copper film layer is covered with a (not-shown) photosensitive/insulating film composed of an epoxy resin having a thickness of about 25 μm. This insulating film is exposed to an exposure and a development, and the exposed portion or the unexposed portion is removed with a peeling liquid.

As a result, the not-shown plated resist profiling the aforementioned pattern is formed on the surface of the thin copper film layer. At the same time, a wide clearance is formed in the surface of the adjoining thin copper film layers over the via holes 20 and 21.

Next, the thin copper film layer positioned on the bottom face of the clearance and in the via holes 20 and 21 is electrically plated with copper. As a result, filled via conductors 22 and 23 are individually formed in the via holes 20 and 21, and wiring pattern layers 24 and 25 to be connected with the via conductors 22 and 23 are formed in the aforementioned clearances.

The wiring pattern layers 24 and 25 and the filled via conductors 22 and 23 can also acquire a strong adhesion to the insulating resin layers 18 and 19, no matter whether the wiring pattern layers 24 and 25 might be narrowed at a fine pitch or the via conductors 22 and 23 might be radially reduced, because the surfaces of the insulating resin layers 18 and 19 adjoining the layers 24 and 25 and the conductors 22 and 23 are roughened.

As shown in FIG. 11, moreover, a solder resist layer (or an insulating layer) 26 made of a resin like before and having a thickness of about 25 μm is formed over the surface of the insulating resin layer 18 having the wiring pattern layers 24 formed thereon. A solder resist layer (or an insulating layer) 27 like before is formed over the surface of the insulating resin layer 19 having the aforementioned wiring pattern layers 25 formed thereon.

The solder resist layers 26 and 27 are bored so deep at predetermined positions with a laser as to reach the wiring pattern layers 24 and 25, thereby to form a land 30 to be opened to a first principal face 28 and an opening 39 to be opened to a second principal face 33a, as shown in FIG. 11.

A solder bump 32 protruding higher than the first first principal face 28 is formed on the land 30, so that electronic parts such as the not-shown IC chip can be mounted over the solder bump 38 through solder. Here, the solder bump 32 is made of an alloy of a low melting point such as Sn—Cu, Sn—Ag or Sn—Zn.

As shown in FIG. 11, moreover, the surface of a wiring line 33, which extends from the wiring pattern layer 25 20 and which is positioned on the bottom face of an opening 31, is plated, although not shown, with Ni or Au to provide connection terminals to be connected with a printed substrate such as the not-shown mother board.

Through the individual steps thus far described, it is possible to provide a wiring substrate K, which comprises the built-up layer BU1 and the built-up layer BU1 over the surface 2 and the back 3 of the core substrate 1, as shown in FIG. 11. The built-up layer BU1 includes the wiring pattern layers 16 and 24 wired at the fine pitch, and the built-up layer BU2 includes the wiring pattern layers 17 and 25.

Here, the wiring substrate K may also be formed to have the built-up layer BU1 exclusively over the surface 2 of the core substrate 1. In this mode, only the wiring layer 17 and the solder resist layer 27 are formed on the side of the back 3.

According to the process for manufacturing the wiring substrate K of the invention thus far described, the wiring pattern layers 16, 24, 17 and 25 and the filled via conductors 12, 22, 13 and 23 can also acquire the strong adhesion to the insulating resin layers 6, 18, 7 and 19., because the surfaces of the insulating resin layers 6, 18, 7 and 19 adjoining therewith are roughened, as described hereinbefore. Moreover, the insulating resin layers 6, 18, 7 and 19 contain a large quantity of inorganic filler and have lower elongations and thermal expansion coefficients and higher Young's moduli than those of the prior art, so that the aforementioned adhesion can be stably kept no matter whether the wiring pattern layers 16, 24 and soon might be formed at the fine pitch or the via conductors 12, 22 and so on might be radially reduced. Thus, the process of the invention can contribute to the manufacture of the wiring substrate which matches the finer pitch of the wiring pattern layers and the radial reduction of the via conductors.

The invention should not be limited to the mode of embodiment thus far described.

The individual steps of the aforementioned manufacturing process may also be performed by a large-sized multi-panel having a plurality of core substrates 1 or core units.

Moreover, the material for the core substrate should not be limited to the aforementioned BT resin but may be exemplified by an epoxy resin or a polyimide resin. Alternatively, it is also possible to use a composite material which is prepared by containing glass fibers in a fluorine resin having a three-dimensional net structure such as PTFE having continuous pores.

Alternatively, the material of the aforementioned core substrate may be ceramics. This ceramics may be alumina, silicic acid, glass ceramics or aluminum nitride, and may also be exemplified by a low-temperature sintered substrate which can be sintered at a relatively low temperature such as about 1,000° C. Moreover, a metal core substrate made of a copper alloy or a Ni alloy containing 42 wt. % of Fe may be used and is covered all over its surface with an insulating material.

Moreover, the mode may also be modified into a coreless substrate having no core substrate. In this modification, for example, the aforementioned insulating resin layers 12 and 13 act as the insulating substrate of the invention.

Moreover, the material for the aforementioned wiring layers 4 and 5 may be not only the aforementioned Cu (copper) but also Ag, Ni or Ni—Au. Alternatively, the wiring layers 4 and 5 do not use the metal-plated layer but may also be formed by a method of applying a conductive resin.

Moreover, the aforementioned insulating resin layers 6 and 7 and so on may also be exemplified, if it contains the aforementioned inorganic filler and has the aforementioned individual properties, not only by the aforementioned resin containing mainly an epoxy resin or but also by a polyimide resin, a BT resin or a PPE resin, which has similar heat resistance and pattern forming properties, or a resin-resin composite material which is prepared by impregnating a fluorine resin having a three-dimensional net structure such as PTFE having continuous pores with a resin such as an epoxy resin.

Moreover, the via conductors need not be the aforementioned filled via conductor 12 but can be an inverted conical conformable via conductor which is not filled therein completely with a conductor. Alternatively, the via conductors may take a staggered shape, in which they are stacked while being axially shifted, or a shape, in which a wiring layer extending midway in the planar direction is interposed.

This application is based on Japanese Patent application JP 2003-388491, filed Nov. 18, 2003, the entire content of which is hereby incorporated by reference, the same as if set forth at length.

1. A process for manufacturing a wiring substrate, comprising a roughening step of roughening surfaces of insulating resin layers, at least one of the insulating resin layers containing an epoxy resin which contains 30 to 50 wt. % of an inorganic filler of SiO₂ having an average grain diameter of 1.0 to 10.0 μm,
wherein the roughening step includes a roughening step of dipping in a solution of permanganic acid at 70 to 85° C. for 20 minutes or longer.

2. The process according to claim 1, wherein each of the insulating resin layers contains the epoxy resin.

3. The process according to claim 1, wherein at least one of the insulating resin layers contains 50 to 70 wt. % of the epoxy resin.

4. The process according to claim 1, wherein at least one of the insulating resin layers after the roughening step has a center line average roughness of 0.2 to 1.0 μm.

5. The process according to claim 1, wherein each of the insulating resin layers after the roughening step has a center line average roughness of 0.2 to 1.0 μm.

6. The process according to claim 1, wherein the solution of permanganic acid includes sodium permanganate or potassium permanganate.

7. The process according to claim 1, wherein at least one of the insulating resin layers has an elongation of 6% or less and more than 0%.

8. The process according to claim 1, wherein each of the insulating resin layers has an elongation of 6% or less and more than 0%.

9. The process according to claim 1, wherein at least one of the insulating resin layers has a Young's modulus of 3.6 to 5.0 Gpa.

10. The process according to claim 1, wherein each of the insulating resin layers has a Young's modulus of 3.6 to 5.0 Gpa.

11. The process according to claim 1, wherein at least one of the insulating resin layers has a thermal expansion coefficient in a planar direction of 50 ppm/° C. or less and more than 0 ppm/° C.

12. The process according to claim 1 wherein each of the insulating resin layers has a thermal expansion coefficient in a planar direction of 50 ppm/° C. or less and more than 0 ppm/° C.

13. The process according to claim 1, further comprising, after the roughening step, a step of forming wiring pattern layers on the roughened surfaces of the insulating resin layers.

14. The process according to claim 1, further comprising, after the roughening step, a step of forming via conductors on roughened inner wall faces of via holes formed through the insulating resin layers.
